(19) United States
(12) Patent Application Publication
(10) Pub. No.: US 2025/0306455 A1
(43) Pub. Date: Oct. 2, 2025

(54) PLANARIZATION PROCESS, APPARATUS AND METHOD OF MANUFACTURING AN ARTICLE

(71) Applicant: CANON KABUSHIKI KAISHA, Tokyo (JP)

(72) Inventors: Seth J. Bamesberger, Austin, TX (US); Byung-Jin Choi, Austin, TX (US); Steven C. Shackleton, Austin, TX (US); Masaki Saito, Austin, TX (US)

(21) Appl. No.: 19/236,818

(22) Filed: Jun. 12, 2025

Related U.S. Application Data
(63) Continuation of application No. 18/049,128, filed on Oct. 24, 2022.

(51) Int. Cl. G03F 7/00

(52) U.S. Cl. CPC G03F 7/0002

(57) ABSTRACT

A planarization system, comprising a superstrate chuck including a holding surface configured to hold a superstrate, an inflatable membrane having an inner diameter defining an inner edge, an outer diameter defining an outer edge, and, a midpoint between the inner edge and the outer edge in a radial direction, wherein the inflatable membrane is disposed radially outward of the holding surface of the superstrate chuck, and a purge gas channel disposed radially inward of the midpoint of the inflatable membrane and radially outward of the holding surface of the superstrate chuck.

### CROSS-REFERENCE TO RELATED APPLICATIONS

This application is a continuation of U.S. patent application Ser. No. 18/049,128 filed on Oct. 24, 2022, which is hereby incorporated by reference herein in its entirety.

### BACKGROUND

### Field of Art

The present disclosure relates to planarization apparatus, and more particularly, to a planarization with modulating thin membrane to control the atmosphere between a mask and a substrate.

### Description of the Related Art

Imprint and planarization techniques are useful in fabricating semiconductor devices. For example, the process for creating a semiconductor device includes repeatedly adding and removing material to and from a substrate. This process can produce a layered substrate with an irregular height variation (i.e., topography), and as more layers are added, the substrate height variation can increase. The height variation has a negative impact on the ability to add further layers to the layered substrate. Separately, semiconductor substrates (e.g., silicon wafers) themselves are not always perfectly flat and may include an initial surface height variation (i.e., topography). One method of addressing this issue is to planarize the substrate between layering steps. Various lithographic patterning methods benefit from patterning on a planar surface. In ArF laser-based lithography, planarization improves depth of focus (DOF), critical dimension (CD), and critical dimension uniformity. In extreme ultraviolet lithography (EUV), planarization improves feature placement and DOF. In nanoimprint lithography (NIL) planarization improves feature filling and CD control after pattern transfer.

A planarization technique sometimes referred to as inkjet-based adaptive planarization (IAP) involves dispensing a variable drop pattern of polymerizable material between the substrate and a superstrate, where the drop pattern varies depending on the substrate topography. A superstrate is then brought into contact with the polymerizable material after which the material is polymerized on the substrate, and the superstrate removed. Improvements in nanoimprint lithography and planarization techniques, including IAP techniques, are desired for improving, e.g., whole substrate processing, step and repeat processing, and semiconductor device fabrication.

### SUMMARY

A planarization system, comprising a superstrate chuck including a holding surface configured to hold a superstrate, an inflatable membrane having an inner diameter defining an inner edge, an outer diameter defining an outer edge, and, a midpoint between the inner edge and the outer edge in a radial direction, wherein the inflatable membrane is disposed radially outward of the holding surface of the superstrate chuck, and a purge gas channel disposed radially inward of the midpoint of the inflatable membrane and radially outward of the holding surface of the superstrate chuck.

A planarizing method, comprises applying a purging gas from a nozzle to an area below a superstrate chuck, wherein the superstrate chuck includes a holding surface holding a superstrate, expanding an inflatable membrane disposed radially outward of the holding surface of the superstrate chuck until a predetermined distance between the inflatable membrane and a surface opposing the inflatable membrane is reached, contacting formable material on a substrate with the superstrate to spread the formable material, and contracting the inflatable membrane to maintain the predetermined distance and to maintain a predetermined concentration of the purging gas in the area below the superstrate chuck during the spreading of the formable material.

These and other aspects, features, and advantages of the present disclosure will become apparent upon reading the following detailed description of exemplary embodiments of the present disclosure, when taken in conjunction with the appended drawings, and provided claims.

### BRIEF DESCRIPTION OF DRAWINGS

So that features and advantages of the present invention can be understood in detail, a more particular description of embodiments of the invention may be had by reference to the embodiments illustrated in the appended drawings. It is to be noted, however, that the appended drawings only illustrate typical embodiments of the invention and are therefore not to be considered limiting of its scope, for the invention may admit to other equally effective embodiments.

FIG. 1 is a diagram illustrating a planarization apparatus that may be applied to imprint process;

FIG. 2A to 2C illustrates a planarization and/or imprint process;

FIG. 3 is an enlarged view of a part of the planarization apparatus with the inflatable membrane and the applique;

FIG. 4A is a bottom view of the superstrate chuck with the inflatable membrane;

FIG. 4B is a cross-sectional view of the superstrate chuck with the inflatable membrane;

FIG. 4C is a close-up view of FIG. 4B;

FIG. 5A shows one side of the inflatable membrane facing the applique;

FIG. 5B shows the side of the inflatable membrane mounted to the superstrate chuck;

FIG. 5C is a cross-sectional view of the inflatable membrane cutting from the line across the pneumatic supply port;

FIG. 5D shows the chamber before a pressure is applied thereto;

FIG. 5E shows the chamber after a pressure is applied thereto;

FIG. 6 shows an example of the inflated inflatable membrane;

FIG. 7A is a cross section close-up view of a portion of FIG. 3 in accordance with an example embodiment;

FIG. 7B is a cross section close-up view of a portion of FIG. 3 in accordance with another example embodiment;

FIG. 8 shows the substrate chuck with the purge gas channel; and

FIG. 9 shows the process flow of control amount of purge gas used for planarization process.

FIGS. 10A to 10I show schematic cross sections of the planarization apparatus during a portion of the process of FIG. 9.

Throughout the figures, the same reference numerals and characters, unless otherwise stated, are used to denote like features, elements, components or portions of the illustrated embodiments. Moreover, while the subject disclosure will now be described in detail with reference to the figures, it is done so in connection with the illustrative exemplary embodiments. It is intended that changes and modifications can be made to the described exemplary embodiments without departing from the true scope and spirit of the subject disclosure as defined by the appended claims.

### DETAILED DESCRIPTION

### Planarization System

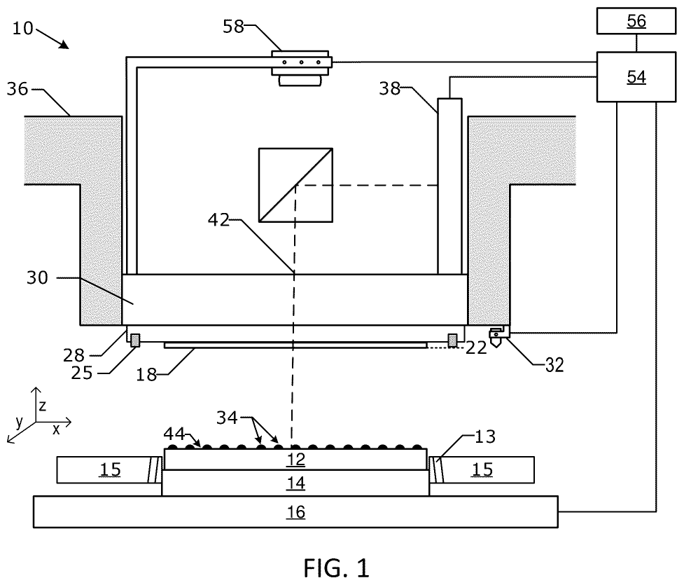

FIG. 1 illustrates a nanoimprint and/or planarization system 10 in which an embodiment may be implemented. The system 10 may be used to planarize the substrate 12 or form a relief pattern on substrate 12. Substrate 12 may be coupled to substrate chuck 14. As illustrated, substrate chuck 14 is a vacuum chuck. Substrate chuck 14, however, may be any chuck including, but not limited to, vacuum, pin-type, groove-type, electrostatic, electromagnetic, and/or the like.

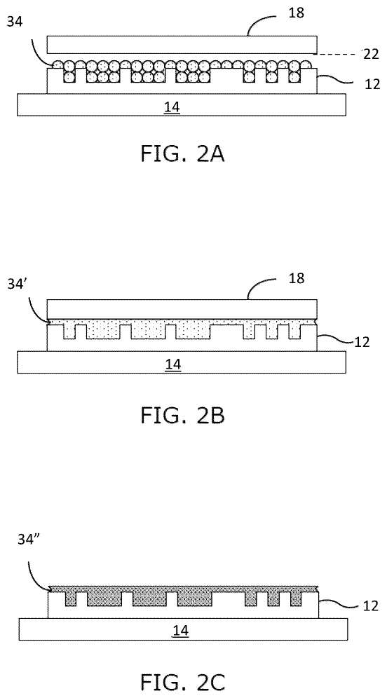

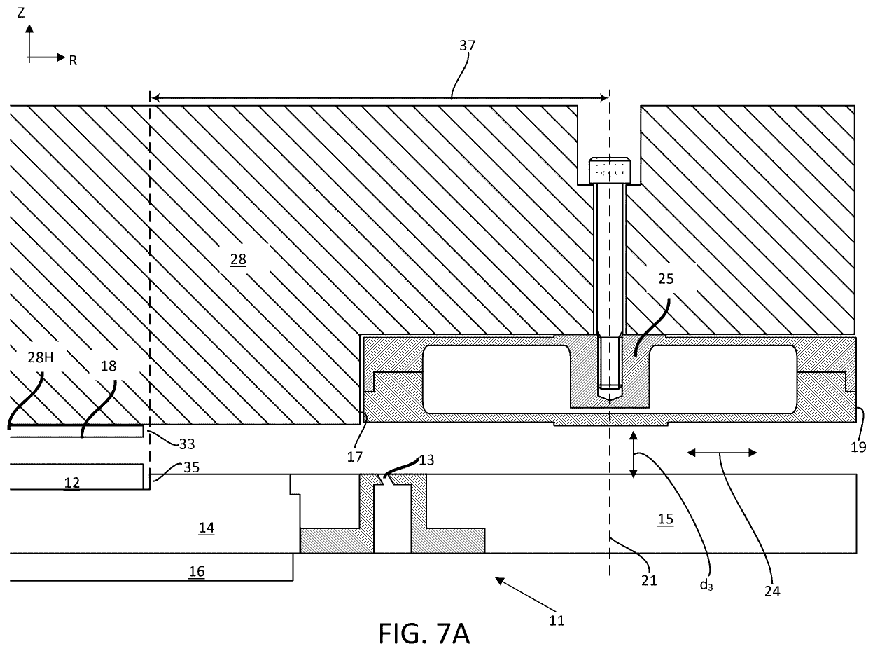

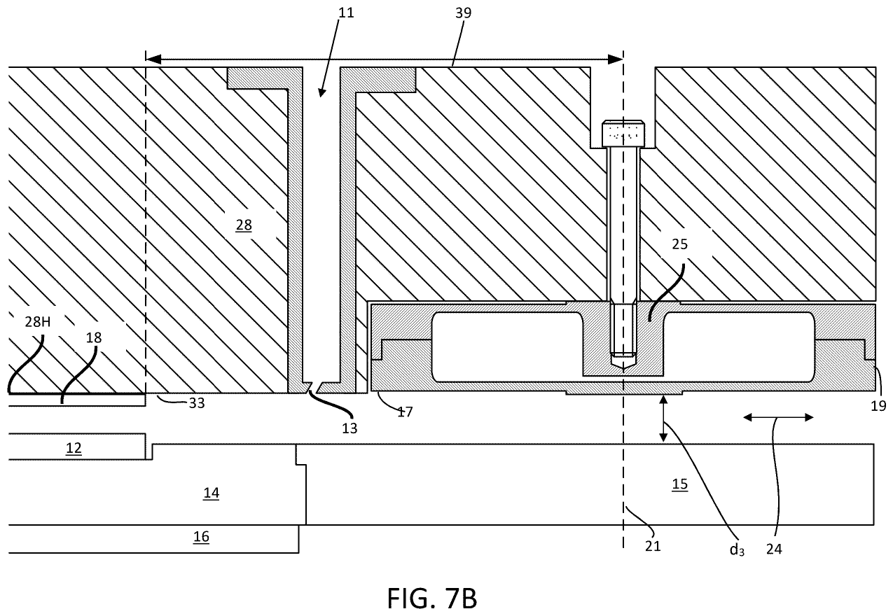

The substrate 12 and the substrate chuck 14 may be further supported by positioning stage 16. The stage 16 may provide translational and/or rotational motion along one or more of the x, y, z, θ, and ϕ axes. The stage 16, the substrate 12, and the substrate chuck 14 may also be positioned on a base (not shown). In one embodiment, the substrate 12 and the substrate chuck 14 may be surrounded by an adjacent member, namely, an applique 15. The applique 15 may be a single piece extending along a side surface of the substrate chuck 14 and a part of the side surface of the substrate 12. The applique 15 may have a rectangular profile, circular profile, hexagonal profile, or a profile in any other geometric shape. A purge gas channel 11 may be formed to perforate through the applique 15 (see FIG. 7A) to allow purge gas supplied from a purge gas source to the space between the substrate 12 and the superstrate 18 spaced-apart from the substrate 12. In another example embodiment, the purge gas channel 11 may be formed to perforate through the superstrate chuck 14 (see FIG. 7B). The superstrate 18 is used to planarize the substrate 12. The superstrate is a flat planar member. In an alternative embodiment the superstrate 18 is a template 18. The template 18 may include a body having a first side and a second side with one side having a mesa (also referred to as mold) extending therefrom towards the substrate 12. The mesa may have a shaping surface 22 (see FIG. 2A) thereon. Alternatively, the template 18 may be formed without a mesa.

The template 18, that is, the superstrate 18, and/or the mold may be formed from such materials including, but not limited to, fused-silica, quartz, silicon, organic polymers, siloxane polymers, borosilicate glass, fluorocarbon polymers, metal, hardened sapphire, and/or the like. As illustrated, shaping surface 22 may be a planar surface or may comprise features defined by a plurality of spaced-apart recesses and/or protrusions, though embodiments of the present invention are not limited to such configurations. The shaping surface 22 may define any original pattern that forms the basis of a pattern to be formed on the substrate 12. The shaping surface 22 may be blank, i.e. without pattern features, in which case a planar surface can be formed on the substrate 12. In an alternative embodiment, when the shaping surface 22 is of the same areal size as the substrate, a layer can be formed over the entire substrate (e.g., whole substrate processing). In an alternative embodiment, when the shaping surface 22 is smaller than the substrate, a layer can be formed over a portion of the substrate one at a time which is then repeated to cover the entire substrate (e.g., step and repeat processing).

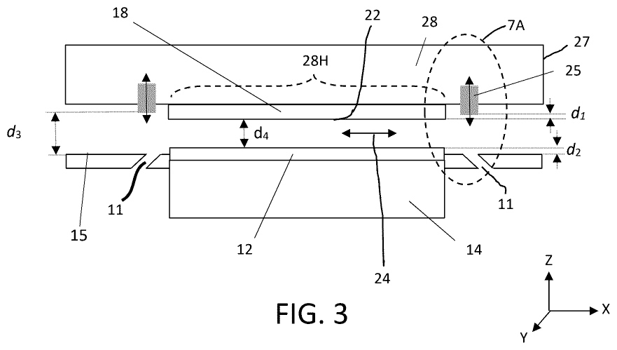

The superstrate 18 (template 18) may be coupled to a holding surface 28H (see FIG. 3) of a superstrate chuck 28 (template chuck 28). The superstrate chuck 28 may be configured as, but not limited to, vacuum, pin-type, groove-type, electrostatic, electromagnetic, and/or other similar chuck types. Further, the superstrate chuck 28 may be coupled to a head 30 which in turn may be moveably coupled to a bridge 36 such that superstrate chuck 28, the head 30 and the template 18 are moveable in at least the z-axis direction. An inflatable membrane 25 extends from a periphery of the superstrate chuck 28. As shown in FIG. 1, the inflatable membrane 25 extending from the periphery surrounding the holding surface 28H and at least a portion of the superstrate 18. A detailed description of the inflatable membrane 25 will be provided later. In an alternative embodiment, the inflatable membrane 25 extends from a periphery of the applique 15. It yet another example embodiment the inflatable membrane 25 is composed of two inflatable membranes, one of which extends from the applique 15 and the other of which extends from the superstrate chuck 28. That is, in a two-component embodiment, there may be a first inflatable membrane in the applique 15 and a second inflatable membrane in the superstrate chuck. These two inflatable membranes can be independently expanded and/or contracted to achieve the same function as a single inflatable membrane.

The system 10 may further comprise a fluid dispense system 32. Fluid dispense system 32 may be used to deposit a formable material 34 (e.g., polymerizable material) on substrate 12. The formable material 34 may be positioned upon the substrate 12 using techniques such as drop dispense, spin-coating, dip coating, chemical vapor deposition (CVD), physical vapor deposition (PVD), thin film deposition, thick film deposition, and/or the like. The formable material 34 may be disposed upon the substrate 12 before and/or after a desired volume is defined between the superstrate 18 (mold) and the substrate 12 depending on design considerations.

The fluid dispense system 32 may use different technologies to dispense the formable material 34. When the formable material 34 is capable of jetting, ink jet type dispensers may be used to dispense the formable material. For example, thermal ink jetting, microelectromechanical systems (MEMS) based ink jetting, valve jet, and piezoelectric ink jetting are common techniques for dispensing jettable liquids.

The system 10 may further comprise radiation source 38 that directs actinic energy along a path 42. The head 30 and the stage 16 may be configured to position the template 18 and the substrate 12 in superimposition with the path 42. A camera 58 may likewise be positioned in superimposition with the path 42. The system 10 may be regulated by a processor 54 in communication with the stage 16, the head 30, the fluid dispense system 32, the source 38, and/or the camera 58 and may operate on a computer readable program stored in a memory 56.

Either the head 30, the stage 16, or both vary a distance between the superstrate 18 (mold) and the substrate 12 to define a desired volume therebetween that is filled by the formable material 34. For example, head 30 may apply a force to superstrate (template) 18 such that the shaping surface 22 contacts the formable material 34. After the desired volume is filled with the formable material 34, the source 38 produces actinic energy (e.g., ultraviolet radiation) causing the formable material 34 to solidify and/or cross-link conforming to a shape of a surface 44 of the substrate 12 and the surface 22 of the template 18, defining a formed layer on the substrate 12.

### Planarization Process

The planarization process and nanoimprint process include steps which are shown schematically in FIGS. 2A to FIG. 2C which may make use of the planarization or the nanoimprint system 10 configured to perform the planarization process or nanoimprint process. As illustrated in FIG. 2A, the formable material 34 in the form of droplets is dispensed and spread onto the substrate 12. As discussed previously, the substrate surface has some topography which may be known based on previous processing operations or may be measured using a profilometer, AFM, SEM, or an optical surface profiler based on optical interference effect like Zygo NewView 8200. The local volume density of the deposited formable material 34 is varied depending on the substrate topography and/or the template topography. The superstrate 18 is then positioned in contact with the formable material 34. As used herein, template and superstrate are used interchangeably to describe an object with a shaping surface 22 that is brought into contact with the formable material 34 to control the shape of the formable material 34. As used herein, template chuck 28 and superstrate chuck 28 are used interchangeably to hold the template 18 or the superstrate 18.

FIG. 2B illustrates a post-contact step after the superstrate 18 has been brought into full contact with the formable material 34 but before a polymerization process starts. The superstrate 18 is equivalent to the template 18 in FIG. 1 and is substantially featureless (may include alignment or identification features) and may be substantially the same size and shape as the substrate (a characteristic dimension such as average diameter of the superstrate 18 may be within at least 3% of a characteristic dimension of the substrate 12). In an alternative embodiment, the superstrate 18 is a template 18 may be smaller than the substrate and may have a shaping surface 22 with features that used to form features in the cured layer 34″. As the superstrate 18 contacts the formable material 34, the droplets merge to form a formable material film 34′ that fills the space between the superstrate 18 and the substrate 12. Preferably, the filling process happens in a uniform manner without any air or gas bubbles being trapped between the superstrate 18 and the substrate 12 in order to minimize non-fill defects. The polymerization process or curing of the formable material 34 may be initiated with actinic radiation (e.g., UV radiation). For example, radiation source 38 of FIG. 1 can provide the actinic radiation causing formable material film 34′ to cure, solidify, and/or cross-link, defining a cured planarized layer 34″ or a cured layer 34″ which may include features on the substrate 12. Alternatively, curing of the formable material film 34′ can also be initiated by using heat, pressure, chemical reaction, other types of radiation, or any combination of these. Once cured, the cured layer (planarized layer) 34″ is formed, the superstrate 18 can be separated therefrom. FIG. 2C illustrates the cured (planarized) layer 34″ on the substrate 12 after separation of the superstrate 18.

### Structure/Process for Eliminating Non-Fill Defects

During the process for spreading the formable material on the substrate, non-fill defects caused by oxygen trapped within the formable material may be created. To eliminate the non-fill defects, purge gas such as helium (He), carbon dioxide, nitrogen, volatile components of the formable material, etc. may be introduced to purge ambient gas from between the formable material and the superstrate (template) 18, so as to remove the trapped oxygen (or other ambient gas that interferes with the process) from underneath the superstrate (template) 18. Non-fill defects can be formed by trapped gas that prevents droplets from merging or prevents curing of the formable material by the actinic radiation. The purge gas is a gas that easily passes through or is incorporated into the substrate, superstrate, or formable material or is easily pushed out when the droplets merge with each other. The target purge gas consumption may be multiple liters per planarization process. Efficient helium purging over a large substrate such as a 300 mm wafer is challenging. To reduce the purge gas consumption per planarization, an annular modulating thin membrane (i.e., inflatable membrane) has been developed and integrated in the planarization apparatus. FIG. 1 1 shows the planarization apparatus 10 that incorporate the inflatable membrane 25. The inflatable membrane surrounding the superstrate 18 may be pressurized to expand towards the plane of the applique, so to create an inflatable boundary and reduce the distance between the applique 15 and the superstrate chuck 28. By reducing the distance between the applique 15 and the superstrate chuck 28, the outward flow of the purge gas is reduced to improve the purging efficiency.

FIG. 3 is an enlarged schematic cross section view of a part of the system 10 in which the superstrate chuck 28 includes the inflatable membrane 25 coupled to the superstrate chuck 28 in accordance with an example embodiment. The inflatable membrane 25 may be mounted to a peripheral region of the superstrate chuck that extends around the holding surface 28H for retaining the superstrate 18, such that the superstrate 18 is circumferentially surrounded by the inflatable membrane 25. That is, the inflatable membrane 25 may be disposed radially outward of the holding surface 28H of the superstrate chuck 28 (i.e., the edges of the holding surface 28H are located closer to the center of the superstrate chuck 28 than the inflatable membrane 25). Preferably, the inflatable membrane 25 is also located radially inward of the outer edge 27 of the superstrate chuck 28 (i.e., the inflatable membrane 25 is located closer to the center of the superstrate chuck 28 than the outer edge 27 of the superstrate chuck 28). In another embodiment (not illustrated), the inflatable membrane 25 may be located in the applique 15. In the embodiment as shown in FIG. 3, the superstrate 18 extends from the holding surface 28H of the superstrate chuck 28 towards the substrate 12 with a distance di between a bottom plane of the bottom surface of the inflatable membrane 25 and a plane of a shaping surface 22 of the superstrate 18. The distance between the bottom surface (that is, the surface facing the applique 15) of the inflatable membrane 25 and the applique 15 is denoted as d₃. The distances d₃ and d₁ vary while pressure is supplied to the inflatable membrane 25 and a distance between the superstrate chuck 28 and the substrate chuck 14 is varied. For example, the distance d₃ is minimized during gas purging and the bottom surface of the inflatable membrane 25 does extend past the plane of the shaping surface 22. At/near the end of the spreading of the formable material 34 by the superstrate 18 to form a formable material film 34′, the bottom surface of the inflatable membrane 25 does not extend past the plane of the shaping surface 22. The top surface (the surface facing the inflatable membrane 25) of the applique 15 is recessed from the top surface (that is, the surface facing the superstrate 18) of the substrate 12 with a distance d₂. The distance d₂ may vary depending on the thickness of the substrate 12 which may vary depending on previous processing steps. The top surface of the applique position relative to substrate chucking surface of the substrate chuck 14 may be fixed or adjustable. The distance between the superstrate 18 and the substrate 12 ranges between about 500 to 4000 μm during gas purging and may be sufficiently large enough to allow a robot hand holding a component such as substrate or superstrate to enter between the chucks 14 and 28 and load the component onto the respective chuck during a loading process.

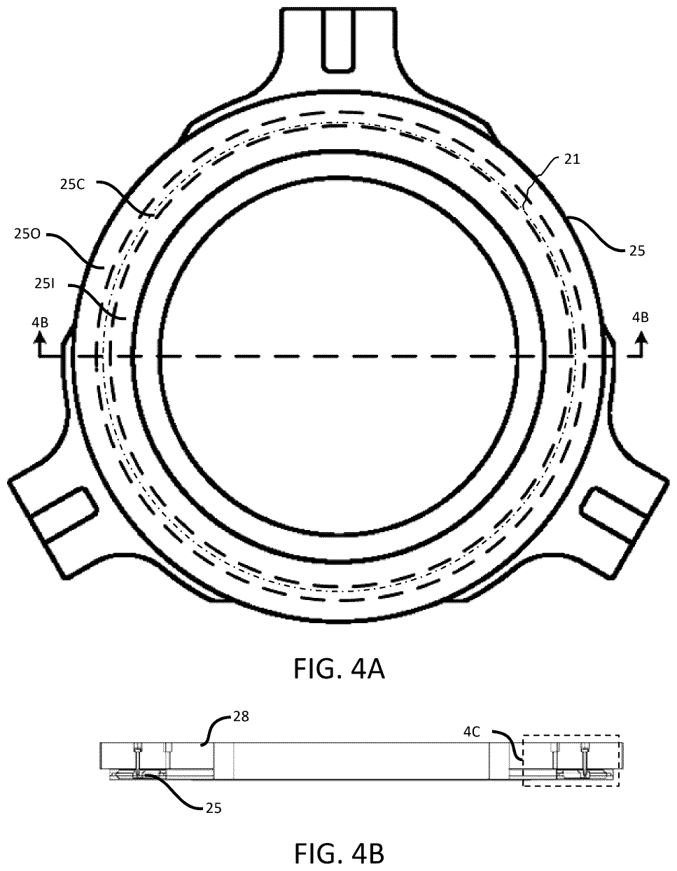

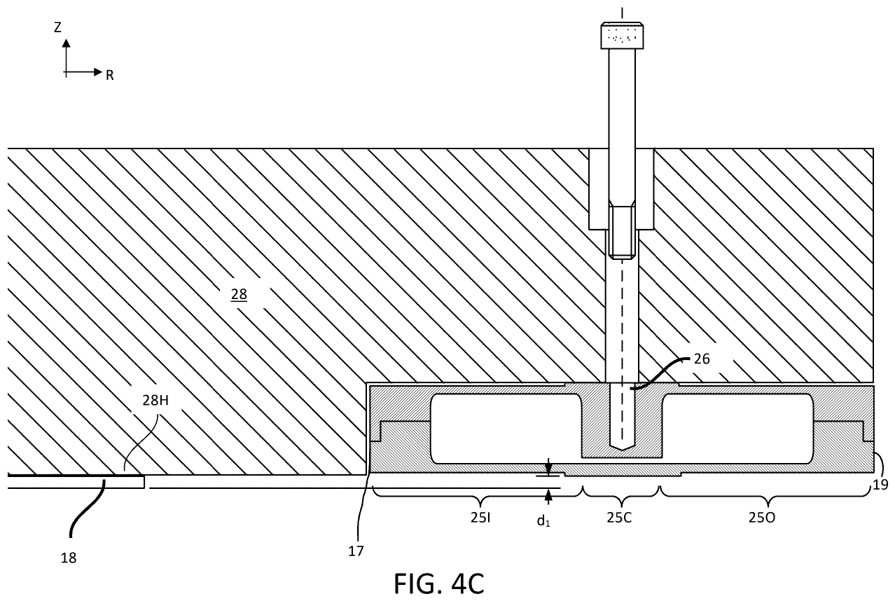

FIG. 4A shows a bottom view of the superstrate chuck 28 with the inflatable membrane 25 mounted to the peripheral region of the superstrate chuck 28. The inflatable membrane 25 is divided into three regions, for example, three concentric annular ring portions, including an outer ring part 25O and an inner ring part 25I divided by a central ring part 25C. FIG. 4B is a close-up in cross sectional view of the superstrate chuck 28 with the inflatable membrane 25 mounted to the peripheral region around the holding surface 28H of the superstrate chuck 28. FIG. 4C is a close-up view of the inflatable membrane 25 mounted to the peripheral region of the superstrate chuck 28. The inflatable membrane 25 may be bolted to the superstrate chuck 28 by one or more of the bolting structure 26 at the central ring part 25C. Near the end of the planarization spreading process, during a loading process, or during a centering process in which the substrate stage centers the substrate under the superstrate, the bottom surface of the inflatable membrane 25 is recessed from the shaping surface 22 (the surface facing the substrate 12) of the superstrate 18 with a distance d₁ to avoid contact with the applique 15 or the substrate chuck 14 by releasing the positive pressure or by applying negative pressure in the inflatable membrane 25. In one embodiment, the distance d₁ is about 300 μm.

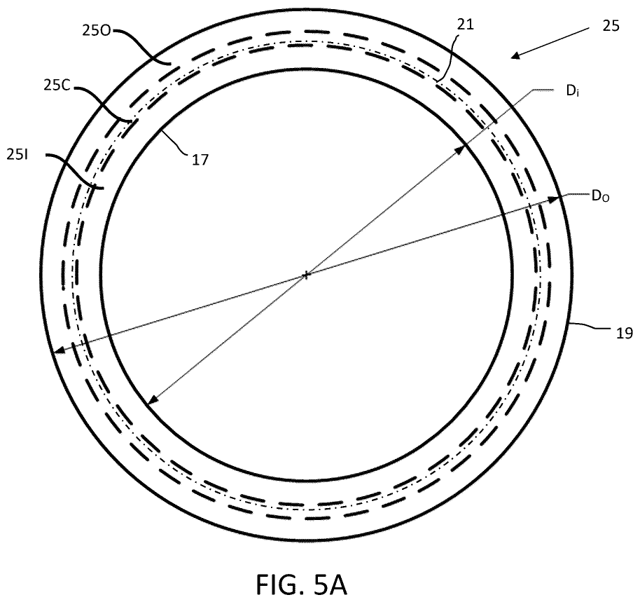

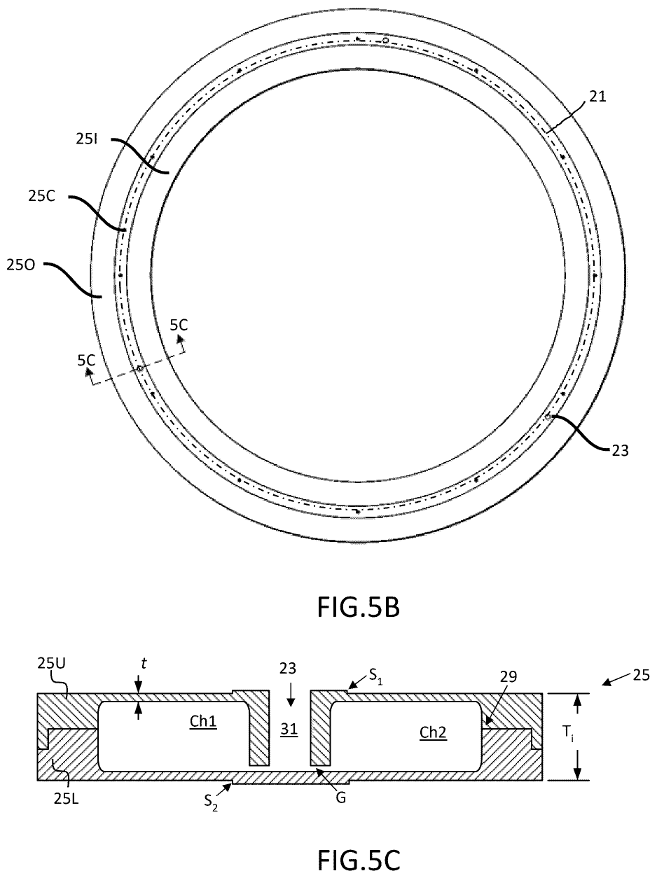

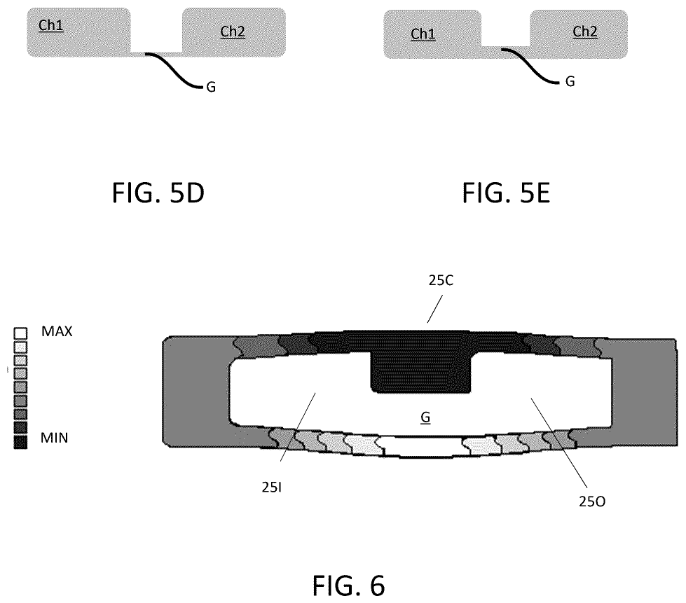

FIGS. 5A and 5B shows two opposite sides of the inflatable membrane 25. The inflatable membrane 25 has an inner diameter Dᵢ defining an inner edge 17 and an outer diameter Dₒ defining an outer edge 19. In one embodiment, the dimension of the inflatable membrane 25, including an initial peripheral thickness Tᵢ (that is, the thickness before being inflated), the inner diameter Dᵢ of about 345 mm and the outer diameter Dₒ of about 435 mm. The dimension of the inflatable membrane 25 may vary depending on the substrate size, the size of the superstrate, the material for forming the inflatable membrane (for example, metal or plastic), or other process conditions. The inflatable membrane 25 may be assembled to the superstrate chuck 28 by a bolting structure, for example, by the multiple bolting structures 26 formed in the central ring part 25C. The central ring part 25C further includes one or more annular ports 23 as shown in FIGS. 5B and 6 to supply the inflatable membrane with pressure to modulate the shape of the inflatable membrane 25 (i.e., a modulation system). The modulation system may include a pressure source which may include one or more gas/vacuum/liquid: connectors; lines; valves; mass flow controllers; pumps; gauges; etc. that are used to control the pressure inside the inflatable membrane.

The inflatable membrane 25 may take the form of a single sealed part with an upper deformable membrane 25U and a lower deformable membrane 25L joined with each other at a joint plane 29 as shown in FIG. 5C. A welding process, for example, ultrasonic welding or laser welding, may be used to weld the upper deformable membrane 25U with the lower deformable membrane 25L. The inflatable membrane 25 may be made as a single article which can be formed using a variety of methods such as injection molding or 3D printing. A first chamber portion Ch1 and a second chamber portion Ch2 are defined within the inner ring part 25I and the outer ring part 25O, respectively, by the central ring part 25C. Fluid and/or pressure may be supplied from the one or more pneumatic supply ports (channels) 23 into the chamber portions Ch1 and Ch2 through the channel 31. The chamber portions Ch1 and Ch2 are concentric ring hollow parts. The pressure supplied to the one or more supply ports 23 may come from a pressure source that may supply positive pressure or negative pressure (for example vacuum) which causes the chamber to inflate and deflate. As shown in FIG. 5C, the bottom of central ring 25C is spaced with the inner bottom surface of the lower membrane with a small gap G. When the pressure is applied to the inside of the inflatable membrane 25, the pressure may be supplied to the chamber portions Ch1 and Ch2 through the gap G. FIG. 5D shows the cross-sectional view of the chamber (including the chambers portions Ch1, Ch2, and the gap G) before the chamber is inflated. The central ring part 25C that divides the chamber into two chamber portions Ch1 and Ch2 also serves as a hard stop when negative pressure is supplied to the one or more supply ports 23 causing the inflatable membrane to deflate. When the inflatable membrane 25 is inflated, and the chamber portions Ch1 and Ch2 are expanded as shown in FIGS. 5E and 6. In one embodiment, the top surface of the upper membrane 25L has a thickness t of about 600 μm to about 1000 μm above the chamber portions Ch1 and Ch2. In one embodiment, a step S₂ is formed under each of the chamber portions Ch1 and Ch2. The top surface of upper membrane 25U may also have a step S₁. The inclusions of steps S1 and S2 may help with the manufacturing of the membranes 25U and 25L and are not necessary for the function of the inflatable membrane 25. However, when the steps S1 and S2 are indeed present, the added thickness is taken into account for maintaining the desired distance d₃during the planarization process. FIG. 6 shows the inflation of the inflatable membrane 25 when a pressure of about 8 kPa is supplied into the chamber portions Ch1 and Ch2.

FIG. 7A is a cross section close-up view of the portion 7A of FIG. 3 in accordance with an example embodiment. As shown in FIG. 7A, in addition to the inflatable membrane 25, the system 10 may include the purge gas channel 11 terminating in one or more nozzles 13. In the example embodiment shown in FIG. 7A, the purge gas channel 11, along with the nozzles 13, is formed in the applique 15. As noted above, the purge gas channel 11 may be in communication with an external gas source. For example, the external gas source may be helium, carbon dioxide, argon, organic vapor (e.g., a component of the formable materiel in vapor form), nitrogen, and/or combinations thereof. As noted above, the inflatable membrane 25, and shown in FIG. 7A, the inflatable membrane 25 may have inner edge 17 defined by an inner diameter Dᵢ and an outer edge 19 defined by an outer diameter Dₒ. The inflatable membrane further includes a midpoint 21 located between the inner edge 17 and the outer edge 19 in a radial direction 24. As shown in FIG. 7A, the purge gas channel 11 and the nozzles 13 are disposed such that the purge gas channel 11 and nozzles 13 are located radially inward of the midpoint 21 of the inflatable membrane 25 (i.e., the purge gas channel 11 and the nozzles 13 are closer to center of the superstrate chuck 28 than the midpoint 21 of the inflatable membrane 25). As also shown in FIG. 7A, the purge gas channel 11, along with the nozzles 13, is further disposed such that the purge gas channel 11 and nozzles 13 are located radially outward of the holding surface 28H of the superstrate chuck 28 (i.e., an edge 33 of the holding surface 28H is located closer to the center of the superstrate chuck 28 than the purge gas channel 11 and nozzles 13). More preferably, in the embodiment shown in FIG. 7A, the purge gas channel 11 and the nozzles 13 are disposed such that the purge gas channel 11 and nozzles 13 are located radially outward of an inner retaining edge 35 of the substrate chuck 14 (i.e., the inner retaining edge 35 of the substrate chuck 14 is located closer to the center of the superstrate chuck 28 than the purge gas channel 11 and the nozzles 13). This preferable area where purge gas channel 11 and the nozzles 13 are radially inward of the midpoint 21 and radially outward of the edge 35 is denoted by arrow 37 which represents a radial positioning range 37 of the nozzle 13 relative to other components of the planarization system 10. The particular position of the purge gas channel 11 and nozzles 13 shown in FIG. 7A is one example implementation where the nozzles 13 is approximately underneath the inner edge 17 of the inflatable membrane 25. However, the nozzles 13 may be located anywhere radially inward of the midpoint 21 of the inflatable membrane while also being radially outward of the holding surface 28H.

FIG. 7B is a close-up view similar to that of FIG. 7A, except that the purge gas channel 11 and the nozzles 13 are differently located, in accordance with another example embodiment. As above, in addition to the inflatable membrane 25, the system 10 may include the purge gas channel 11 terminating in the nozzles 13. However, in the example embodiment shown in FIG. 7B, the purge gas channel 11, along with the nozzles 13, is formed in the superstrate chuck 28. As shown in FIG. 7B, the purge gas channel 11 and the nozzles 13 are similarly disposed such that the purge gas channel 11 and nozzles 13 are located radially inward of the midpoint 21 of the inflatable membrane 25 (i.e., the purge gas channel 11 and the nozzles 13 are closer to center of the superstrate chuck 28 than the midpoint 21 of the inflatable membrane 25). In the case where the nozzles 13 and the inflatable membrane are located on the same side as illustrated in FIG. 7B then the nozzles 13 are located radially inward of the inner diameter D₁, i.e., radially inward of the inner edge 17. As also shown in FIG. 7B, the purge gas channel 11, and the nozzles 13, are further disposed such that the purge gas channel 11 and nozzles 13 are located radially outward of the holding surface 28H of the superstrate chuck 28 (i.e., an edge 33 of the holding surface 28H is located closer to the center of the superstrate chuck 28 than the purge gas channel 11 and nozzles 13). This area where purge gas channel 11 and the nozzles 13 are radially inward of the midpoint 21 and radially outward of the edge 33 of the holding surface 28H is denoted by arrow 39. The particular position of the purge gas channel 11 and nozzles 13 shown in FIG. 7B is one example implementation where the nozzles 13 is adjacent the inner edge 17 of the inflatable membrane 25. However, the nozzles 13 may be located anywhere radially inward of the midpoint 21 of the inflatable membrane while also being radially outward of the edge 33 of the holding surface 28H.

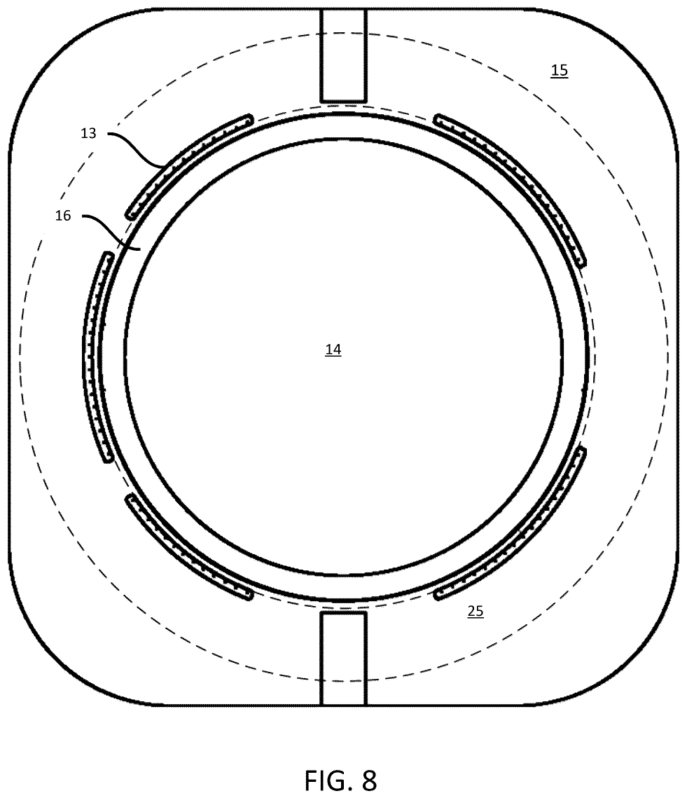

FIG. 8 shows a top view of the substrate stage 16 on which a substrate chuck 14 is loaded. In the embodiment shown in FIG. 8, the substrate chuck 14 includes the nozzles 13 perforated through the applique 15. Through the nozzles 13, the purging gas is supplied between the substrate 12 retained with the substrate chuck 14 and the superstrate 18 retained with the superstrate chuck 28 (see FIG. 3). The embodiment as shown in FIG. 8 includes five curved slits (which include the inserts in which the purge gas lines 11 are located) extending along a holding surface of the substrate chuck 14 and their position relative to a location of the region below the membrane 25 (shown with dashed lines). While FIG. 8 shows the example embodiment where the purge gas channel 11 and nozzles 13 (illustrated in FIG. 8 as dots in the five curved slits) are located in the applique 15 (e.g., corresponding to FIG. 7A), it should be understood that the same principle may be applied to the example embodiment where the purge gas channel and the nozzles 13 are located in superstrate chuck 28 (e.g., corresponding to FIG. 7B). In yet another embodiment, there may be two sets of purge gas channels and nozzles, where one set is located in the applique and one set is located in the superstrate chuck in a single system. It will be appreciated that the shape, the number, and the position of the nozzles may be varied according to the specific process needs.

When the substrate stage 16 moves from the loading position to the planarization position, that is, the position under the planarization head for performing spreading of formable material 34 during the planarization process on the substrate, at least a part of the nozzles 13, namely, motion side nozzles, located in the applique 15 are turned on for initial purge until the substrate stage 16 is centered with the planarization head. In an alternative embodiment, the substrate stage 16 is centered with the planarization head 30 during the loading process. When the substrate stage 16 is centered with the planarization head 30 in the planarization position, pressure is supplied through the pneumatic supply port 23 to inflate the inflatable membrane 25, such that a desired distance d₃ between the applique 15 and the inflatable membrane 25 is maintained, and an inflatable boundary is created. That is, the inflatable membrane 25 expands toward the applique 15 in the illustrated example embodiment. All nozzles 13, or part of the nozzles 13 referred to as gas purge nozzles, are turned on to supply purging gas into the space between the superstrate 18 and the substrate 12 to efficiently purge away the ambient gas to prevent non-fill and other defects from forming in the cured layer 34″ applied on the substrate 12 (see FIG. 1). When the concentration of the purge gas within the space reaches the required concentration, the nozzles 13 may remain on with a reduced gas flow or completely turned off. When the spreading process is complete, a negative pressure may be supplied into the inflatable membrane 25 or the positive pressure may be released until the chamber reaches equilibrium with the environment. The negative pressure deflates the inflatable membrane 25 to increase the distance between the inflatable membrane 25 and the applique 15 only after the spreading process has finished, such that undesired particles created by contact between the surfaces can be prevented and the purge gas is substantially constrained around the superstrate during the spreading process.

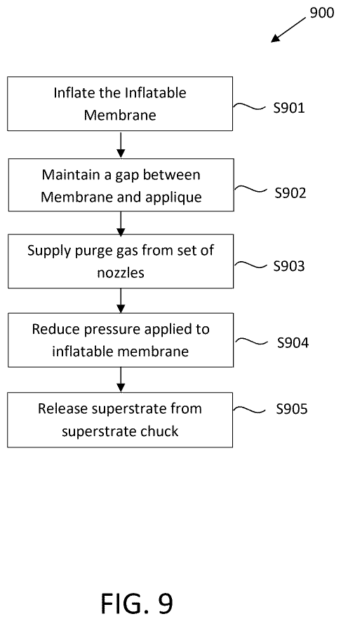

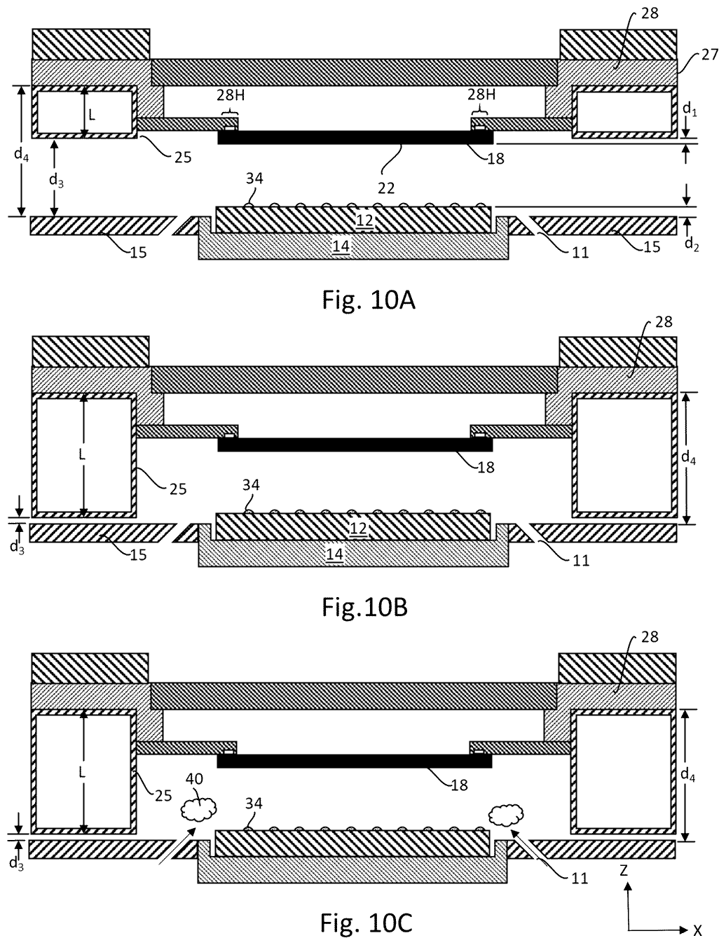

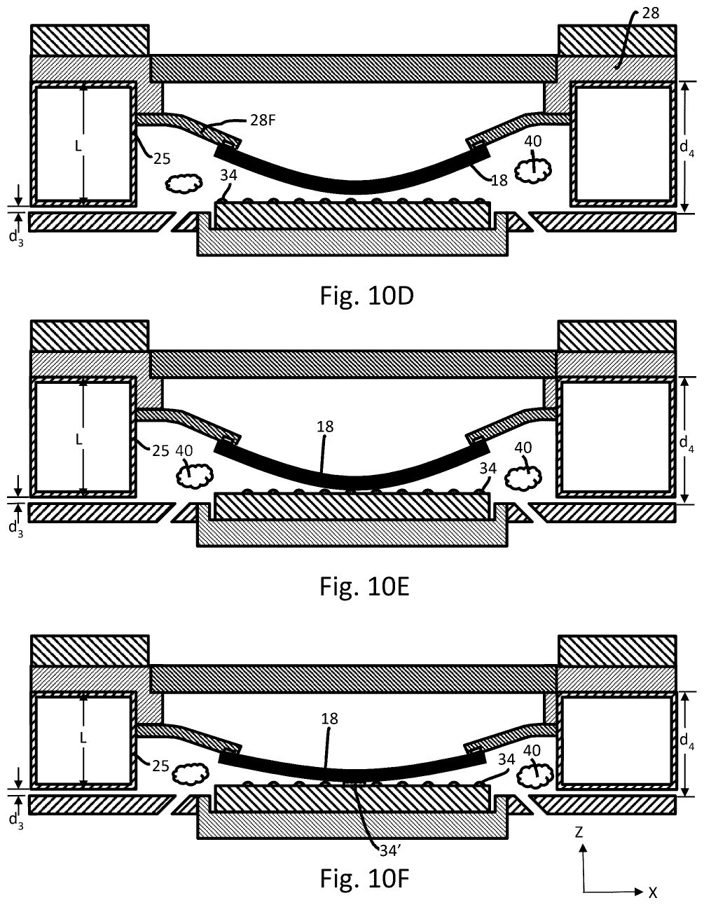

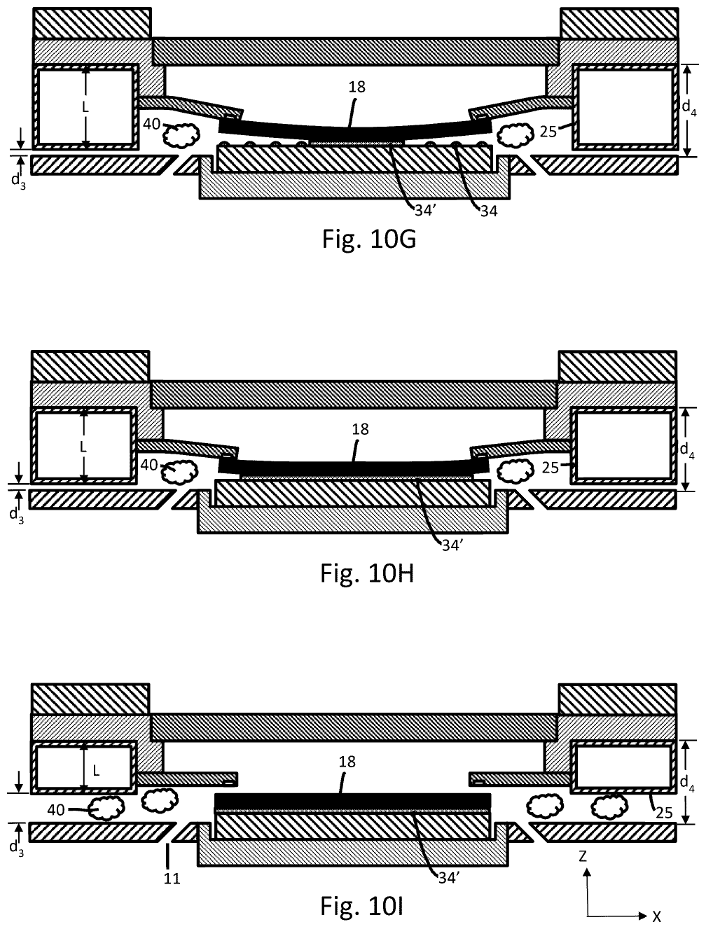

FIG. 9 shows a flow chart of a method 900 to control an amount purge gas that is sufficient for removing or preventing the creation of non-fill or other defects during spreading. FIGS. 10A to 10I show schematic cross sections of the planarizing system at particular points during a planarizing process that includes the method of FIG. 9. FIG. 10A shows a moment in the planarizing method when the substrate 12, having formable material 34 on the surface, is located beneath the superstrate 22 held by the superstrate chuck 28. As shown in FIG. 10A, at this moment, the inflatable membrane 25 is in a fully deflated/retracted position. That is, at the moment shown in FIG. 10A, the inflatable membrane has not yet been pressurized and is in a default/base state. In an alternative embodiment, negative (vacuum) pressure is applied the chambers of the inflatable membrane. The moment shown in FIG. 10A is just prior to step S901 of FIG. 9. Four distances are illustrated in FIG. 10A. The first distance, d₁, as noted above, is the distance between a bottom plane of the bottom surface of the inflatable membrane 25 and a plane of a shaping surface 22 of the superstrate 18. As noted above, the second distance, d₂, is the distance between the top surface (the surface facing the inflatable membrane 25) of the applique 15 and the top surface (the surface facing the superstrate 18) of the substrate 12. As noted above, the third distance, d₃, is the distance between the bottom surface (the surface facing the applique 15) of the inflatable membrane 25 and the applique 15. A fourth distance, d₄, is a distance between the top surface (the surface facing the chuck 28) of the inflatable membrane 25 and the top surface (the surface facing the inflatable membrane 25) of the applique 15. FIG. 10A also shows a length L of the inflatable membrane in the Z direction. At the moment shown in FIG. 10A, the length L is at a minimum value because the inflatable membrane 25 has not yet been expanded at all.

In step S901, the inflatable membrane 25 is pressurized and inflated (i.e., expanded) towards the applique 15 until the distance d₃ becomes a predetermined value. That is, a predetermined/desired distance for d₃ is known in advance of expanding the inflatable membrane 25 and the expanding continues as part of step S901 until distance d₃ reaches the predetermined value. In the example embodiment shown in FIG. 10B, the distance d₄ has not changed during the step of expanding the inflatable membrane 25. In other words, during the step of expanding the inflatable membrane 25 until the distance d₃ reaches the predetermined value, the superstrate chuck 28 has not moved closer to the substrate 12/substrate chuck 14. Thus, the value of d₄ in FIG. 10A is the same in both FIGS. 10A and 10B, while d₃ has become much smaller from FIG. 10A (prior to expanding the inflatable membrane) to FIG. 10B (after expanding the inflatable membrane). In one example embodiment, the predetermined value that d₃ becomes in FIG. 10B is 1 to 1000 μm, 5 to 500 μm, or 10 to 100 μm. The particular predetermined value for d₃ may be selected such that, during spreading of the formable material, leakage of the purge gas is minimized, while particles created by a contact between the inflatable member 25 and the applique 15 is prevented. In an embodiment, the predetermined value is less than the distance d₂. Likewise, because the inflatable membrane 25 has expanded to reach the predetermined value for d₃, the length L of the inflatable membrane 25 is much larger in FIG. 10B as compared to the length L of the inflatable membrane 25 is FIG. 10A. For example, the length L may be 1 to 20 μm, 5 to 15 μm, or 7 to 10 μm. The ratio of the length L in FIG. 10B to the length L in FIG. 10A may be 1.1:1 to 3:2.

Once reached, the predetermined value for d₃ is maintained throughout the spreading of the formable material on the substrate, as discussed below. The method may then proceed to step S902 where the purging gas 40 from the nozzle 13 is supplied to the region between the chucks and the inflatable membrane via the purge gas channel 11. This moment of supplying the purge gas of step S902 is shown in FIG. 10C, where the arrows through the purge gas channel 11 represent the active moment of supplying of the purge gas 40. As shown in FIG. 10C, at this moment, there is no change in the distance d₃ and the distance d₄ as compared to FIG. 10B. That is, when the purge is supplied, superstrate chuck 28 has not been moved closer to the substrate chuck (hence the distance d₄ is the same as in FIG. 10B) and the amount of expansion of the inflatable membrane 25 has not changed (hence the distance d₃ and the length L is the same as in FIG. 10B).

The supply of the purge gas 40 through the nozzles 13 via the purge gas channel 11 may continue until a predetermined concentration of the purge gas in the area surrounding the substrate has been reached. Once the predetermined concentration is reached, the supply of the purge gas may be terminated. In another embodiment, the supply of purge gas may continue even after the predetermined concentration is reached.

After the predetermined purge gas concentration has been reached, the method may proceed to step S904 where the pressure applied to inflatable membrane 25 is reduced, as part of the process of forming a film of the formable material. However, prior to reducing the pressure in the inflatable membrane, a preliminary step in the process of forming the film may be performed. This preliminary step is shown in FIG. 10D. As shown in FIG. 10D, the superstrate 18 may be bowed outwardly toward the substrate 12, along with flexing of a flexible portion 28F of the superstrate chuck 28. The flexible aspect of the superstrate chuck 28 is described in U.S. Pat. App. Pub. No US20220115259, which is hereby incorporated by reference in its entirety. In an alternative embodiment, a superstrate chuck 28 that does not include a flexible portion 28 F is used, in which case the superstrate may be bowed by applying positive pressure to a central portion of the superstrate with the superstrate chuck 28 while still holding the superstrate along the periphery with for example vacuum pressure (superstrate may also be held by other means including electrostatic or mechanical means). The detailed process of using a superstrate chuck with flexible portion are described therein. Returning to FIG. 10D, the superstrate 18 has been bowed toward the substrate 12 and the flexible portion 28F of the superstrate chuck 28 has been flexed toward the substrate 12. However, the superstrate chuck 28 has not yet moved toward the substrate 12 in the Z direction. Thus, as shown in FIG. 10D, the distance d₄ has not yet changed as compared to FIG. 10C. Accordingly, at the preliminary step shown in FIG. 10D, there is not yet a need to reduce the pressure in the inflatable membrane 25 to maintain the predetermined value for distance d₃ because there is not yet a change in the distance d₄. In other words, until distance d₄ begins to get smaller, the predetermined value for d₃ will stay the same even though the superstrate 18 has been bowed such that the superstrate 18 is closer to the substrate 12. Thus, in FIG. 10D all of the d₃, L, and d₄ are the same as in FIG. 10C.

FIG. 10E shows a moment where the substrate chuck 28 has moved closer to the substrate 12 in the Z direction with the superstrate 18 fully bowed, where the superstrate 18 is just beginning to come into contact with drops of formable material 34. That is, in the moment shown in FIG. 10E, the bowing discussed above with respect to 10D is maintained while the superstrate chuck 28 has been moved in the Z direction to a location where the superstrate 18 is just beginning to contact the drops of formable material 34. Accordingly, because the superstrate chuck 28 has moved toward the substrate 12 in the Z direction (and the substrate 12 has not moved in the Z direction), the distance d₄ in FIG. 10E is smaller than the distance d₄ in FIG. 10D. While the superstrate chuck is moved toward a stationary substrate in the illustrated embodiment, in other example embodiments the superstrate chuck may be stationary while the substrate chuck moves the substrate toward the superstrate. In yet another embodiment, both the superstrate chuck and the substrate may move toward each other. However, as noted above, the predetermined value for the distance d₃ is to be maintained throughout the process of forming the film 34′. Thus, FIG. 10E also shows a moment when the step S904 has begun to be implemented, where the pressure in inflatable membrane 25 has been reduced to decrease the length L of the inflatable membrane in the Z direction while maintaining the predetermined value for d₃. The amount of reduction in the pressure in the inflatable membrane 25 is precisely controlled so that the length L of the inflatable membrane 25 in the Z direction is decreased just enough to maintain the predetermined value of distance d₃. In summary, in the moment shown in FIG. 10E, distance d₄ is smaller in FIG. 10E than the distance d₄ in FIG. 10D, length L is smaller in FIG. 10E than length L in FIG. 10D, and distance d₃ is the same (the predetermined value) in both FIGS. 10D and 10E. Furthermore, the amount of decrease of distance d₄ from FIG. 10D to FIG. 10E is the same amount of decrease of length L from FIG. 10D to FIG. 10E. The purge gas concentration remains substantially the same in the moment shown in FIG. 10E as compared to the moment shown in FIG. 10D.

FIG. 10F shows a moment after the moment shown in FIG. 10E, where the superstrate chuck 28 has continued to move toward the substrate 12 in the Z direction, while the superstrate begins to flatten as the film of formable material 34′ begins to form (see also US20220115259). Because the superstrate chuck 28 has moved toward the substrate 12 in the Z direction (and the substrate 12 has not moved in the Z direction), the distance d₄ in FIG. 10F is smaller than the distance d₄ in FIG. 10E. However, as noted above, the predetermined value for the distance d₃ is to be maintained throughout the process of forming the film 34′. Thus, FIG. 10F shows another moment of the step S904, where the pressure in inflatable membrane 25 has been further reduced to further decrease the length L of the inflatable membrane in the Z direction. The amount of reduction in the pressure in the inflatable membrane 25 in FIG. 10F is continued to be precisely controlled so that the length L of the inflatable membrane 25 in the Z direction is decreased just enough to maintain the predetermined value of distance d₃. In summary, in the moment shown in FIG. 10F, distance d₄ is smaller in FIG. 10F than the distance d₄ in FIG. 10E, length L is smaller in FIG. 10F than length L in FIG. 10E, and distance d₃ is the same (the predetermined value) in both FIGS. 10E and 10F. Furthermore, the amount of decrease of distance d₄ from FIG. 10E to FIG. 10F is the same amount of decrease of length L from FIG. 10E to FIG. 10F. The purge gas concentration remains substantially the same in the moment shown in FIG. 10F as compared to the moment shown in FIG. 10E.

FIG. 10G shows a moment after the moment shown in FIG. 10F, where the superstrate chuck 28 has continued to move toward the substrate 12 in the Z direction, while the superstrate continues to flatten as the film of formable material 34′ continues to form. Because the superstrate chuck 28 has moved toward the substrate 12 in the Z direction (and the substrate 12 has not moved in the Z direction), the distance d₄ in FIG. 10G is smaller than the distance d₄ in FIG. 10F. However, as noted above, the predetermined value for the distance d₃ is to be maintained throughout the process of forming the film 34′. Thus, FIG. 10G shows another moment of the step S904, where the pressure in inflatable membrane 25 has been further reduced to further decrease the length L of the inflatable membrane in the Z direction. The amount of reduction in the pressure in the inflatable membrane 25 in FIG. 10G is continued to be precisely controlled so that the length L of the inflatable membrane 25 in the Z direction is decreased just enough to maintain the predetermined value of distance d₃. In summary, in the moment shown in FIG. 10G, distance d₄ is smaller in FIG. 10G than the distance d₄ in FIG. 10F, length L is smaller in FIG. 10G than length L in FIG. 10F, and distance d₃ is the same (the predetermined value) in both FIGS. 10F and 10G. Furthermore, the amount of decrease of distance d₄ from FIG. 10F to FIG. 10G is the same amount of decrease of length L from FIG. 10F to FIG. 10G. The purge gas concentration remains substantially the same in the moment shown in FIG. 10G as compared to the moment shown in FIG. 10F.

FIG. 10H shows a moment after the moment shown in FIG. 10G, where the superstrate chuck 28 has continued to move toward the substrate 12 in the Z direction, while the superstrate is nearly completely flattened as the film of formable material 34′ is nearly completely formed. Because the superstrate chuck 28 has moved toward the substrate 12 in the Z direction (and the substrate 12 has not moved in the Z direction), the distance d₄ in FIG. 10H is smaller than the distance d₄ in FIG. 10G. However, as noted above, the predetermined value for the distance d₃ is to be maintained throughout the process of forming the film 34′. Thus, FIG. 10H shows another moment of the step S904, where the pressure in inflatable membrane 25 has been further reduced to further decrease the length L of the inflatable membrane in the Z direction. The amount of reduction in the pressure in the inflatable membrane 25 in FIG. 10H is continued to be precisely controlled so that the length L of the inflatable membrane 25 in the Z direction is decreased just enough to maintain the predetermined value of distance d₃. In summary, in the moment shown in FIG. 10H, distance d₄ is smaller in FIG. 10H than the distance d₄ in FIG. 10G, length L is smaller in FIG. 10H than length L in FIG. 10G, and distance d₃ is the same (the predetermined value) in both FIGS. 10G and 10H. Furthermore, the amount of decrease of distance d₄ from FIG. 10G to FIG. 10H is the same amount of decrease of length L from FIG. 10G to FIG. 10H. The purge gas concentration remains substantially the same in the moment shown in FIG. 10G as compared to the moment shown in FIG. 10G.

FIG. 10I shows a moment after the film 34′ has been fully formed or almost completely formed and the superstrate 18 has been released from the superstrate chuck 28. FIG. 10I corresponds with step S905 of the method 900. That is, just after the moment shown in FIG. 10H, the method 900 may proceed to step S905 where the superstrate 18 is released. The superstrate 18 may be released in the manner described in US20220115259. However, along with releasing the superstrate 18, it is no longer necessary to maintain the predetermined value for d₃ because the film 34′ has been fully formed. Thus, as shown in FIG. 10I, at the same time that the superstrate 18 has been released from the superstrate chuck 28 or soon after, even though the superstrate chuck 28 has not moved upward in the Z direction (i.e., d₄ is the same as FIG. 10H), the pressure in the inflatable membrane 25 may be greatly reduced so that the d₃ is much larger than the predetermined value. In an alternative embodiment, the pressure in the inflatable membrane 25 is maintained so that the distance d₃ is maintained at the predetermined value until curing of the formable material film 34′ becomes the cured film 34″. Likewise, the length L is much smaller in FIG. 10I than in FIG. 10H. In summary, in FIG. 10I (i.e., at the moment of releasing the superstrate 18 from the superstrate chuck 28), d₃ is larger than in FIG. 10H, L is smaller than in FIG. 10H, and d₄ is the same as in FIG. 10H. During this same moment, the supply of purge gas may return if the gas environment around superstrate needs to be maintained after the superstrate is released but before curing ends. By following the process illustrated in FIGS. 10A to 10I, a sufficient amount of purge gas is retained in the area around the substrate such that the creation of non-fill defects or other defects is prevented during spreading of the formable material. The process illustrated in FIGS. 10A-I also reduces the amount of purge gas that needs to be supplied during the shaping process in order to ensure both reduction of non-fill defects and to ensure proper curing of a formable material that is sensitive to being poisoned by ambient gases.

With the film 34′ formed and the superstrate 18 released, following step S905, the overall fabrication process can proceed with the additional processing steps such as curing and removal of the superstrate.

Further modifications and alternative embodiments of various aspects will be apparent to those skilled in the art in view of this description. Accordingly, this description is to be construed as illustrative only. It is to be understood that the forms shown and described herein are to be taken as examples of embodiments. Elements and materials may be substituted for those illustrated and described herein, parts and processes may be reversed, and certain features may be utilized independently, all as would be apparent to one skilled in the art after having the benefit of this description.

What is claimed is:

1. A planarization system, comprising:
a superstrate chuck including a holding surface configured to hold a superstrate;
an inflatable membrane having:
an inner diameter defining an inner edge;
an outer diameter defining an outer edge; and
a midpoint between the inner edge and the outer edge in a radial direction,
wherein the inflatable membrane is disposed radially outward of the holding surface of the superstrate chuck; and
a purge gas channel disposed radially inward of the midpoint of the inflatable membrane and radially outward of the holding surface of the superstrate chuck.

2. The planarization system according to claim 1, further comprising:
a substrate chuck having an inner retaining edge,
wherein the purge gas channel is disposed radially outward of the inner retaining edge.

3. The planarization system according to claim 2,
wherein the superstrate chuck has an outer edge, and
wherein the midpoint of the inflatable membrane is disposed radially inward of the outer edge of the superstrate chuck.

4. The planarization system according to claim 1, further comprising:
one or more nozzles in communication with the purge gas channel,
wherein the one or more nozzles is disposed radially inward of the midpoint of the inflatable membrane and radially outward of the holding surface of the superstrate chuck.

5. The planarization system according to claim 4, further comprising:
a substrate chuck having an inner retaining edge,
wherein the one or more nozzles is disposed radially outward of the inner retaining edge.

6. The planarization system according to claim 4, wherein the one or more nozzles are disposed in the superstrate chuck.

7. The planarization system according to claim 4, further comprising:
a substrate chuck configured to hold a substrate; and
an applique surrounding the substrate chuck,
wherein the one or more nozzles is disposed in the applique.

8. The planarization system according to claim 1, further comprising:
a substrate chuck configured to hold a substrate; and
an applique surrounding the substrate chuck,
wherein the purge gas channel is disposed in the applique.

9. The planarization system according to claim 1,
wherein the purge gas channel is disposed in the superstrate chuck.

10. The planarization system according to claim 1, further comprising:
a substrate chuck configured to hold a substrate;
an applique surrounding the substrate chuck; and
a modulation system to modulate the inflatable membrane, so as to control a distance between the inflatable membrane and the applique.

11. The planarization system according to claim 10, wherein the modulation system comprises a pressure source to pressurize the inflatable membrane such that the inflatable member expands towards the applique before and during a process of spreading formable material on a substrate held by the substrate chuck.

12. The chuck according to claim 1,
wherein the purge gas channel is in communication with a purge gas source, and
wherein the purge gas source comprises a purge gas selected from the group consisting of helium, carbon dioxide, nitrogen, and combinations thereof.

13. The planarization system according to claim 1, wherein the inflatable membrane includes two or more concentric hollow ring parts divided by a concentric central ring part.

14. The planarization system according to claim 13, wherein the concentric central ring part includes one or more bolting structures to mount the inflatable membrane to the chuck.

15. The planarization system according to claim 13, wherein the inflatable membrane includes one or more pneumatic supply channels for pressure to be supplied into the hollow ring parts.

16. The planarization system according to claim 13, wherein the inflatable membrane includes a gap between the central ring part and an inner bottom surface allowing the pressure from the pneumatic supply channels supplied into the hollow concentric ring parts.

17. The planarization system according to claim 13, wherein the inflatable membrane includes a step structure under the concentric central ring.

18. A planarizing method, comprising:
applying a purging gas from a nozzle to an area below a superstrate chuck, wherein the superstrate chuck includes a holding surface holding a superstrate;
expanding an inflatable membrane disposed radially outward of the holding surface of the superstrate chuck until a predetermined distance between the inflatable membrane and a surface opposing the inflatable membrane is reached;
contacting formable material on a substrate with the superstrate to spread the formable material; and
contracting the inflatable membrane to maintain the predetermined distance and to maintain a predetermined concentration of the purging gas in the area below the superstrate chuck during the spreading of the formable material.

19. The planarizing method according to claim 18, wherein the surface opposing the inflatable membrane is a surface of an applique surrounding a substrate chuck.

20. The planarizing method according to claim 18, further comprising:
prior to contacting the formable material with the superstrate, bowing the superstrate toward the substrate;
reducing a bowing amount of the superstrate as the superstrate contacts the formable material; and
contracting the inflatable membrane to maintain the predetermined distance during the reducing of the bowing amount of the superstrate.
